(19) United States
(12) Patent Application Publication
(10) Pub. No.: US 2010/0193883 A1
(43) Pub. Date: Aug. 5, 2010

(54) SEMICONDUCTOR DEVICE AND METHOD OF MANUFACTURING THE SAME

(75) Inventor: TAKASHI HASE, KANAGAWA (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/699,076

(22) Filed: Feb. 3, 2010

(30) Foreign Application Priority Data
Feb. 4, 2009 (JP) 2009-024068

(51) Int. Cl. H01L 29/78; H01L 21/28

(52) U.S. Cl. 257/411; 438/591; 257/E29.255; 257/E21.19

(57) ABSTRACT

Provided is a semiconductor device of the present invention including, a substrate; a Hf-containing insulating film (HfSiON film) provided over the semiconductor substrate; a NiSi fully-silicided electrode for blocking diffusion of at least Hf which composes the insulating film and a metal element which composes the fully-silicided gate electrode, provided over the HfSiON film; and a barrier film (SiOC film) provided between HfSiON film and the NiSi fully-silicided electrode so as to be brought into contact with the NiSi fully-silicided electrode, wherein the NiSi fully-silicided electrode contains either an N-type or a P-type impurity segregated in a portion thereof brought into contact with the SiOC film, and the SiOC film has a dielectric constant not larger than that of a silicon oxynitride film, and contains (i) silicon (Si), (ii) carbon (C), and (iii) oxygen (O) or nitrogen (N), as major constituents.

This application is based on Japanese patent application No. 2009-024068 the content of which is incorporated hereinto by reference.

### BACKGROUND

1. Technical Field

The present invention relates to a semiconductor device a method of manufacturing the same.

2. Related Art

International Patent Publication WO 2004/073072 describes a method of manufacturing a MIS semiconductor device. The method of manufacturing a semiconductor device is aimed at preventing growth of a low-k layer (silicon oxide film) between a substrate and a high-k film in a MOSFET which uses the high-k film as a gate insulating film, according to which a high-k film and a diffusion barrier layer are deposited on the substrate, the high-k film is annealed to modify film properties, a gate electrode material film is then deposited, and the films are then patterned to form a gate electrode. According to the description, the high-k film may be exposed on the side faces thereof to plasma in the process of forming the gate electrode, and may be damaged due to electric charge injected therethrough. For the purpose of allowing the electric charge to leak elsewhere and of restoring the damage, the diffusion barrier layer is provided so as to cover the entire surface including the gate-forming portion, and then annealed. It is also described that, in view of preventing oxidative species such as O₂, H₂O and so forth, remaining in the process atmosphere, from diffusing through the high-k film to reach the interface between the high-k film and the silicon substrate, and to grow there a low-k intermediate layer, the diffusion barrier layer is formed by depositing any one material selected from aluminum oxide, aluminum nitride, aluminum oxynitride, silicon oxide, silicon nitride, silicon oxynitride and silicon carbide, which are highly resistive to permeation of O₂ and H₂O.

Japanese Laid-Open Patent Publication No. 2005-158998 describes a method of manufacturing a semiconductor device, according to which a silicon film, which is processed later to give at least a part of gate electrode, is formed on a gate insulating film, any one of nitrogen, oxygen, fluorine and carbon is introduced into the silicon film, and the silicon film is then annealed to form any one of a nitrided layer, oxidized layer, fluoridated layer and carbonized layer, at the interface between the gate electrode and the gate insulating film. According to the Publication, any defect formed at the interface between the gate electrode which is composed of a polysilicon (or silicon and germanium) film, and the high-k gate insulating film which is composed of a metal element, is repaired by any of a nitrided layer, oxidized layer, fluoridated layer and carbonized layer, which are formed by nitriding agent/oxidation agent/fluoridation agent/carbonization agent supplied through the gate electrode, so that the flat-band voltage becomes less likely to shift, and is successfully lowered to a level equivalent to the case where a silicon oxide film is used as the gate insulating film, and thereby a high-performance semiconductor device having a low threshold voltage may be obtained.

D. Amie et al. describes a semiconductor device in 2004 Symposium on VLSI Technology, “Work Function Tuning through Dopant Scanning and Related Effects in Ni fully Silicided Gate for Sub-45 nm Nodes CMOS”. The semiconductor device has a gate insulating film, and a fully-silicided electrode (simply referred to as FUSI electrode, hereinafter) provided thereon. Amie et al. discuss adoption of a high-k gate insulating film for the purpose of reducing the equivalent oxide thickness, and adoption of metal electrode to the gate electrode for the purpose of preventing the gate electrode from being depleted.

Also the FUSI electrode obtained by allowing the gate electrode, composed of polysilicon or amorphous silicon, to react with a metal so as to convert the entire portion thereof into silicide, is considered as one of expectable metal gate electrodes. For the case where the metal gate electrode is adopted, the work function thereof is necessarily optimized respectively for nMIS and pMIS. More specifically, it is preferable to use a low-work-function electrode on the nMIS side, and a high-work-function metal electrode on the pMIS side. It is described in the literature that, in the process of forming the FUSI electrode, the low-work-function electrode on the nMIS side and the high-work-function electrode on the pMIS side may effectively be obtained, by preliminarily introducing P, As or the like as an n-type impurity on the nMIS side, and by introducing B or the like as a p-type impurity on the pMIS side, into the gate electrode composed of polysilicon or amorphous silicon before being fully silicided, and then by allowing the gate electrodes to undergo full silicidation. This is supposed to be ascribable to that the introduced impurities segregate at the interface between the FUSI electrode and the gate insulating film in an concentrated manner, in the process of full silicidation.

It is also described that the FUSI electrode (referred to as impurity-segregated FUSI electrode, hereinafter) thus obtained by a technique combined with impurity implantation is highly advantageous in that a plurality of work functions may be obtained using only a single kind of metal electrode, and consequently in that the manufacturing processes may be simplified as compared with other metal gate electrode processes.

K. Takahashi et al. describe, in 2004 International Electron Device Meeting, “Dual Work Function Ni-Silicide/HfSiON Gate Stacks by Phase-Controlled Full-Silicidation (PC-FUSI) Technique for 45-nm-Node LSTP and LOP Devices”, that in the process of using a HfSiON gate insulating film, the achievable work function of the gate electrode is constantly 4.5 eV or around, which is equivalent to the level of a non-doped gate electrode, even if fully silicided after being doped with B and P as the impurities.

According to Takahashi et al., the impurity-segregated FUSI electrode no longer shows changes in the work function, which is so-called Fermi level pinning, when the impurity-segregated FUSI electrode and the Hf-containing, high-k gate insulating film are combined, because the impurity-segregated FUSI electrode contains silicon. “Fermi level pinning” herein means a phenomenon observed when the Hf-containing, high-k gate insulating film is combined with a gate electrode composed of polysilicon or amorphous silicon, characterized by fixed work function of the gate electrode at around 4.3 to 4.5 eV, irrespective of impurities introduced thereinto.

In order to avoid Fermi level pinning, it may be effective to provide a barrier film between the impurity-segregated FUSI electrode and the Hf-containing, high-k gate insulating film, so as to suppress Hf from diffusing from the insulating film into the gate electrode. In this case, those having technical commonsense may readily come to an idea of using a silicon nitride film which is known to be a dense film.

It has, however, been difficult to control the work function, even with the above-described method of avoiding Fermi level pinning.

The present inventors found out from teachings of our investigations detailed below, that the dielectric constant increases at the interface of the impurity-segregated FUSI electrode, so that the amount of change in the work function inducible by the segregated impurities decreases, and thereby the control of the work function is made more difficult.

The present inventors investigated into C—V characteristic of a transistor having a gate structure in which a HfSiON gate insulating film and an impurity-segregated FUSI electrode, which contains Ni as a metal, are stacked, and confirmed from the C—V characteristics that the equivalent oxide thickness decreases by approximately 0.3 to 0.4 nm not only in the inversion mode, but also in the accumulation mode, as compared with a transistor having a gate structure in which a HfSiON gate insulating film and a polysilicon electrode are stacked. The present inventors also found out that such decrease in the equivalent oxide thickness in the accumulation mode hardly occurs in a combination of a SiO₂ gate insulating film and an impurity-segregated FUSI electrode.

The above-described decrease in the equivalent oxide thickness may be understood as below. The Hf-containing, high-k gate insulating film is likely to produce therein oxygen vacancy, and consequently contains a large number of dangling bonds of Si atoms. Such Si atoms bind with Ni atoms, and help the Ni atoms diffuse over the surface of the gate insulating film. Since region having the Ni atoms diffused thereover is increased in the dielectric constant, so that the equivalent oxide thickness consequently decreases.

The decrease in the equivalent oxide thickness also affects changes in the work function inducible by the segregated impurity. Given that the segregated impurity produces polarization P at the interface between the HfSiON gate insulating film increased in the dielectric constant and the impurity-segregated FUSI electrode, the amount of change in work function ΔWF inducible by the polarization P may be expressed as below:

ΔWF=PN_{D}/∈ (1)

where, N_{D}: polarization density; and

∈: dielectric constant in the region causing polarization P.

Accordingly, the amount of change in work function ΔWF decreases, if the interface of the impurity-segregated FUSI electrode is increased in the dielectric constant. In other words, since the dielectric constant increases in the HfSiON gate insulating film due to diffusion of Ni atoms, so that the amount of change in work function ΔWF inducible by the segregated impurity decreases a matter of course.

Note that the dense barrier film such as silicon nitride film is also known as a high-k film in general. Provision of this sort of barrier film between the impurity-segregated FUSI electrode and the Hf-containing, high-k gate insulating film increases the dielectric constant at the interface of the FUSI electrode, and thereby the amount of change in work function inducible by the segregated impurity decreases. For this reason, the segregated impurity is supposed to fail in fully exhibiting an effect of modifying the work function, and thereby the control of work function is supposed to made more difficult as described in the above.

As has been described in the above, the present inventors found out a problem of difficulty in control of the work function in the semiconductor device having the Hf-containing, high-k gate insulating film and the impurity-segregated FUSI electrode provided thereon such as those described by Amie et al. and Takahashi et al., even if Fermi level pinning is avoided.

International Patent Publication WO 2004/073072 Pamphlet describes adoption of “aluminum oxide, aluminum nitride, aluminum oxynitride, silicon oxide, silicon nitride, silicon oxynitride, or silicon carbide”, as the “lower diffusion barrier layer for suppressing inclusion of oxidative species (O₂ and H₂O)” provided on the Hf-containing, high-k gate insulating film. These films are, however, incapable of solving the above-described problem for the reason described below. Aluminum oxide, aluminum nitride and aluminum oxynitride, which contain Al as an constitutive element, have large dielectric constants, and are therefore apparently make the control of work function more difficult due to elevated dielectric constants at the interface of the impurity-segregated FUSI electrode. The problem in the silicon nitride is as described in the above. Also silicon oxide and silicon oxynitride are poor in the barrier performance against Hf diffusion, and allows inclusion of Hf as a consequence, and again less expectable in keeping the dielectric constant at a low level. Silicon carbide having no oxygen cannot suppress reaction with the silicidation metal, but is silicided by itself, and is not expectable for keeping the dielectric constant at a low level. As a consequence, the control of work function still remains in difficulty, even if the barrier films described in International Patent Publication WO 2004/073072 Pamphlet are used.

According to Japanese Laid-Open Patent Publication No. 2005-158998, “carbon” is introduced into the “interface between the gate electrode and the gate insulating film” already existing there, so that the resultant “carbonized layer” inevitably contains Hf. For the case where the gate electrode is composed of a silicide, the “carbonized layer” inevitably contains also a metal which composes the silicide. Since the carbonized layer intrinsically contains Hf or the silicide-composing metal element, it is apparent that the carbonized layer described in the Publication is no longer a low-k layer. Since the amount of carbon introduced by the method disclosed in the Publication falls short of the amount enough to be accountable as a major constituent of the “carbonized layer”, so that it is considered difficult for such carbonized layer to suppress diffusion of major constituents such as Hf or the silicide-composing metal. In conclusion, the control of work function still remains in difficulty, even if the carbonized layer described in the Publication is adopted.

### SUMMARY

According to the present invention, there is provided a semiconductor device which includes:

a substrate;

a Hf-containing insulating film provided over the substrate;

a fully-silicided gate electrode provided over the insulating film; and

a barrier film for blocking diffusion of at least Hf which composes said insulating film and a metal element which composes said fully-silicided gate electrode, provided between the insulating film and the fully-silicided gate electrode so as to be brought into contact with the fully-silicided gate electrode;

the fully-silicided gate electrode containing either an N-type or a P-type impurity segregated in a portion thereof brought into contact with the barrier film, and

the barrier film having a dielectric constant not larger than that of a silicon oxynitride film, and containing elements (i), (ii) and (iii) below as major constituents:

(i) silicon (Si);

(ii) carbon (C); and

(iii) oxygen (O) or nitrogen (N).

According to the present invention, there is also provided a method of manufacturing a semiconductor device which includes:

forming a Hf-containing insulating film over a substrate;

forming a barrier film over the insulating film; and

forming a fully-silicided gate electrode so as to be brought into contact with the barrier film,

the fully-silicided gate electrode containing either an N-type or a P-type impurity segregated in a portion thereof brought into contact with the barrier film, and

the barrier film blocking diffusion of at least Hf which composes said insulating film and a metal element which composes said fully-silicided gate electrode, having a dielectric constant not larger than that of a silicon oxynitride film, and containing elements (i), (ii) and (iii) below as major constituents:

(i) silicon (Si);

(ii) carbon (C); and

(iii) oxygen (O) or nitrogen (N).

In the present invention, the barrier film, which contains Si, O and C as major constituents, or contains Si, N and C as major constituents, is provided between the Hf-containing insulating film and the fully-silicided gate electrode. The barrier film blocks diffusion of at least Hf which composes the insulating film and a metal element which composes the fully-silicided gate electrode. Accordingly, also the diffusion of Hf metal may be suppressed, and thereby Fermi level pinning is prevented from occurring. In addition, since the diffusion of the metal element may be suppressed, and since the dielectric constant of the barrier film is smaller than that of the silicon oxynitride film, so that the fully-silicided gate electrode may be prevented from being elevated in the dielectric constant at the interface. Accordingly, the effect of controlling the work function inducible by the segregated impurity may fully be expressed, without reducing the amount of change in work function.

According to the present invention, a semiconductor device, and a method of manufacturing a semiconductor device, capable of controlling the work function inducible by the segregated impurity, may be provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view illustrating a stacked structure of a gate in one embodiment of the present invention;

FIGS. 2A to 2C, FIGS. 3A to 3C, FIGS. 4A to 4C, and FIGS. 5A and 5B are sectional views illustrating a series of processes of manufacturing the semiconductor device in one embodiment; and

FIGS. 6A and 6B, FIGS. 7A and 7B, and FIGS. 8A and 8B are sectional views illustrating a series of processes of manufacturing the semiconductor device in another embodiment.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

Aiming at solving the above-described problems, the present inventors have extensively been investigated into a stacked structure of a Hf-containing, high-k gate insulating film and a fully-silicided gate electrode in a semiconductor device, and a method of manufacturing the same. In particular, keeping difficulty in the control of work function inducible by the segregate impurity in our mind, the present inventors have been making special efforts on removing the difficulty in such stacked structure. Preferred embodiments of the present invention will be explained below, referring to the attached drawings. Note that any similar constituents in all drawings will be given similar reference numerals or symbols, and explanations therefor will not be repeated.

What is brought into our focus was characteristics of the barrier film, and more specifically a balance between the dielectric constant and barrier performance against diffusion of metal.

As descried in the above, the conventional barrier films have been suffering from the problems below. That is, even if a dense barrier film were provided between the impurity-segregated FUSI electrode and the Hf-containing, high-k gate insulating film (simply referred to as “gate insulating film” hereinafter, unless otherwise specifically noted) in order to avoid Fermi level pinning, the amount of change in work function may decrease if the barrier film has a large dielectric constant, and thereby the control of work function with the aid of the segregated impurity is made difficult. On the other hand, even if a barrier film having a small dielectric constant were used, metals such as Hf would migrate into the barrier film, and would elevate the dielectric constant of the fully-silicided gate electrode at the interface thereof, if the barrier film had only a small density. Also in this case, the control of work function with the aid of the segregated impurity will be made difficult.

There is known a general tendency that lowered dielectric constant is accompanied by lowered barrier performance, whereas elevated barrier performance is accompanied by elevated dielectric constant. The present inventors then came to an idea of solving the above-described problems by adopting a barrier film appropriately balanced between the barrier performance and smallness in the dielectric constant. The present inventors found out that a film containing Si, O and C as major constituents, or a film containing Si, N and C as major constituents, and in particular a SiOC film or a SiNC film are preferable as such well-balanced films.

The barrier film herein preferably has a small dielectric constant by nature. By the effect of dielectric constant of the barrier film, the polarization of the segregated impurity may be converted into the amount of change in work function according to the equation (1) in the above. For this reason, the barrier film preferably has a small dielectric constant ∈, if a large amount of change in work function is desired.

It is also preferable that the barrier film contains no metal, which is contained in the fully-silicided gate electrode and the Hf-containing, high-k gate insulating film, as a major constituent. The metal possibly composing the gate insulating film may be exemplified by transition metals such as titanium (Ti), zirconium (Zr) and tantalum (Ta); lanthanoid such as lanthanum (La) and yttrium (Y); and aluminum (Al). This is because the barrier film containing any of these metals as a major constituent may be elevated in the dielectric constant. It is particularly preferable that the barrier film contains none of these metals deep inside thereof.

It is still also preferable that the barrier film does not contain, inside thereof as the major constituents, any metals even if they are other than those contained in the fully-silicided gate electrode and the gate insulating film. This is because any metals present therein may diffuse into the insulating film, to thereby degrade the dielectric characteristics and insulating characteristics of the gate insulating film, or to produce unexpected polarization.

The barrier film is also desired to suppress oxygen vacancy from being formed therein, by blocking diffusion of Hf. This is because, if Hf diffuses to form the oxygen vacancy in the barrier film, the silicide metal diffuses into the vacancy, and thereby the barrier film is supposedly elevated in the dielectric constant as described in the above.

Although a SiOF film may otherwise be an expectable candidate by virtue of its small dielectric constant and desirable barrier performance, fluorine (F) contained therein is an element having an extremely large electron negativity, and may form unexpected polarization in the silicide gate electrode if segregated thereinto. If so, the SiOF film is not suitable as the barrier film of this embodiment.

Details of the embodiment for achieving the above-described effects will be given below, referring to the attached drawings.

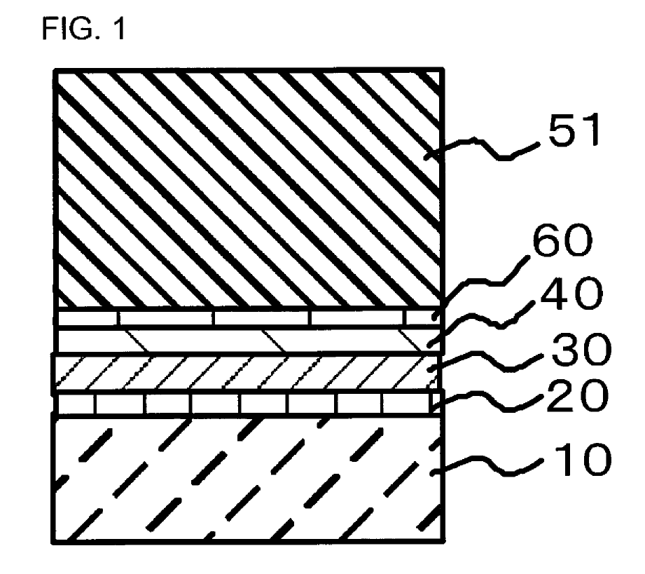

FIG. 1 illustrates a stacked structure of a gate electrode of this embodiment. Note that a SiOC film adopted as the barrier film in the embodiment below may alternatively be replaced by a SiCN film.

The semiconductor device of this embodiment has a substrate (semiconductor substrate 10), a lower insulating film (SiO₂ film 20) provided over the semiconductor substrate 10, a Hf-containing insulating film (HfSiON film 30) provided over the SiO₂ film 20, a fully-silicided gate electrode (NiSi fully-silicided electrode 51) provided over the HfSiON film 30, and a barrier film (SiOC film 40) provided between the HfSiON film 30 and the NiSi fully-silicided electrode 51 so as to brought into contact with the NiSi fully-silicided electrode 51.

The NiSi fully-silicided electrode 51 contains, in a portion thereof brought into contact with the SiOC film 40, either an N-type or P-type impurity 60 segregated therein.

The barrier film has a dielectric constant not larger than that of a silicon oxynitride film, contains elements (i), (ii) and (iii) below as major constituents ((i) silicon (Si), (ii) carbon (C), (iii) oxygen (O) or nitrogen (N)), but contains no metal element which composes the HfSiON film 30 or the NiSi fully-silicided electrode 51, as a major constituent at least inside thereof.

In this embodiment, the NiSi fully-silicided electrode 51 having the impurity 60 segregated therein is used as the impurity-segregated FUSI electrode, and the HfSiON film 30 is used as the Hf-containing, high-k gate insulating film. The barrier film (SiOC film 40) is a film for preventing or blocking diffusion of Ni and Hf. The semiconductor substrate 10 adoptable herein may be a silicon substrate and so forth.

The barrier film (diffusion barrier film) in this embodiment is not specifically limited, so far as the film is any of those containing Si, O and C as the major constituents, or containing Si, N and C as the major constituents, which are characterized by high barrier performance and low dielectric constant. Further, the each element of Si, O and C, or Si, N and C in the barrier film containing Si, O and C as the major constituents, or containing Si, N and C as the major constituents, may exist from a first surface contacting the fully-silicided electrode to a second surface contacting the Hf-containing insulating film of the barrier film. Further, in the barrier film containing Si, O and C as the major constituents, or containing Si, N and C as the major constituents, the composition of the each element of Si, O and C, or Si, N and C may be substantially equal from the first surface contacting the fully-silicided electrode to the second surface contacting the Hf-containing insulating film of the barrier film. In addition, the barrier film of this embodiment has a dielectric constant not larger than that of a silicon oxynitride film from the first surface contacting the fully-silicided electrode to the second surface contacting the Hf-containing insulating film of the barrier film.

The barrier film is aimed at blocking diffusion of metal element which composes fully-silicided gate electrode.

The barrier film may also block diffusion of a metal element which composes the gate insulating film.

The barrier film contains no metal element, which composes the insulating film or the fully-silicided gate electrode, as a major constituent at least inside thereof.

In this embodiment, the barrier film contains neither Hf nor Ni as the metal element at least central region of inside thereof.

The barrier film may be a single-layered film, or a multi-layered film.

The dielectric constant of the barrier film is not specifically limited, so far as it is not larger than that of a silicon oxynitride film, and is capable of suppressing decrease in the amount of change in work function inducible by the segregated impurity. The dielectric constant of the barrier film may still further be not larger than that of a silicon oxide film. The dielectric constant of the barrier film may be adjusted to 7 or smaller, preferably 5 or smaller, and more preferably 3 or smaller.

The thickness of the barrier film is preferably 0.1 nm or larger, and 1 nm or smaller. This is because a thickness of smaller than 0.1 nm may fail in expressing a desired level of barrier performance, whereas a thickness of larger than 1 nm may degrade performance of the device due to elevated operation voltage ascribable to an excessively large thickness of the gate equivalent oxide thickness.

The carbon content of the barrier film is preferably 5% or more in terms of atomic ratio, and 30% or less in terms of atomic ratio. This is because an atomic ratio of smaller than 5% may degrade the barrier performance against diffusion of Hf and Ni, whereas an atomic ratio of larger than 30% may fail in keeping the denseness of the barrier film at a desirable level, and may again degrade the barrier performance against diffusion. The atomic ratio of carbon in the barrier film is preferably 10% or larger, and 20% or smaller.

Method of forming the SiOC film 40 as the barrier film is not specifically limited, and may be exemplified by sputtering of a SiC target in an oxidative atmosphere. In this case, carbon in the SiOC film 40 may tend to reside as an interstitial atom. For the purpose of allowing such carbon to bind with oxygen, the film is preferably formed under heating, or the formation of the film is preferably followed by annealing. The SiOC film 40, if grown by low-temperature PECVD, readily contains a large amount of organic groups to give a low-density film, showing only a poor barrier performance against diffusion in a state as grown. It is therefore necessary for the SiOC film 40 to be densified, typically by post-growth annealing in an inert gas, or by UV irradiation.

As illustrated in FIG. 1, the fully-silicided gate electrode (NiSi fully-silicided electrode 51) is provided on the barrier film (SiOC film 40). At an interfacial portion of the NiSi fully-silicided electrode 51 brought into contact with the Hf-containing gate insulating film (HfSiON film 30), the impurity 60 is segregated according to “snowplow effect” in the silicidation. Dipole is formed between the thus-segregated impurity 60 and element in the SiOC film 40 or in the HfSiON film 30, such as Si, by which Schottky barrier height of the fully-silicided gate electrode may effectively be modulated. The SiOC film 40 herein suppresses both of outward diffusion of Hf from the HfSiON film 30 and outward diffusion of Ni from the NiSi fully-silicided electrode 51. Accordingly, the dielectric constant of the SiOC film 40 is equivalent to that of SiO₂, or smaller by the contribution of carbon which resides therein. As a consequence, the amount of change in work function inducible by the dipole ascribable to the impurity 60 is equivalent to, or larger than the value attainable by a gate insulating film composed of SiO₂.

Metals possibly composing the fully-silicided gate electrode of this embodiment are not specifically limited. Denoting now the metal as “M”, the fully-silicided gate electrode maybe composed of monosilicide or disilicide (MSi or MSi₂). The fully-silicided gate electrode may also have a compositional ratio of metal M larger than that in MSi. The metal M may be exemplified by Ni, Co, Ti and so forth. In this embodiment, Ni is adopted as the metal M composing the fully-silicided gate electrode. In this case, the fully-silicided gate electrode is NiSi or NiSi₂. Still alternatively, the fully-silicided gate electrode may be composed of any one of Ni₂Si, Ni₃₁Si₁₂ and Ni₃Si, each of which has a compositional ratio of Ni larger than that of nickel monosilicide.

The impurity 60 in this embodiment is not specifically limited so far as it is either N-type or P-type. N-type impurity may be selected from phosphorus (P), arsenic (As), antimony (Sb), fluorine (F) and so forth. P-type impurity may be selected from boron (B) and indium (In).

The gate insulating film in this embodiment may be composed of hafnium oxide film, hafnium silicate film, or high-k insulating film which is composed of hafnium oxide or hafnium silicate having nitrogen introduced therein. In this embodiment, the HfSiON film is used as the gate insulating film.

Films adoptable as the lower insulating film are not specifically limited so far as they are insulating films. In this embodiment, the SiO₂ film 20 may be adoptable as the lower insulating film. Besides this, a silicon nitride film, or a stack of a silicon oxide film and a silicon nitride film may be adoptable as the lower insulating film. The thickness of the lower insulating film may be adjustable within practically non-problematic ranges.

The semiconductor device, having the above-described stacked structure of the gate insulating film and the fully-silicided gate electrode, further has a first diffusion layer which is formed in the surficial portion of the semiconductor substrate 10 on one side of the insulating films (SiO₂ film 20, HfSiON film 30), and a second diffusion layer which is formed in the surficial portion of the semiconductor substrate 10 on the other side of the insulating films (SiO₂ film 20, HfSiON film 30). In the thus-configured semiconductor device, a field effect transistor may be configured by the first diffusion layer, the second diffusion layer and the gate electrode (NiSi fully-silicided electrode 51).

The field effect transistor may be an NMIS transistor or may be a PMIS transistor. One of the first diffusion layer and the second diffusion layer is a source diffusion layer, and the other is a drain diffusion layer.

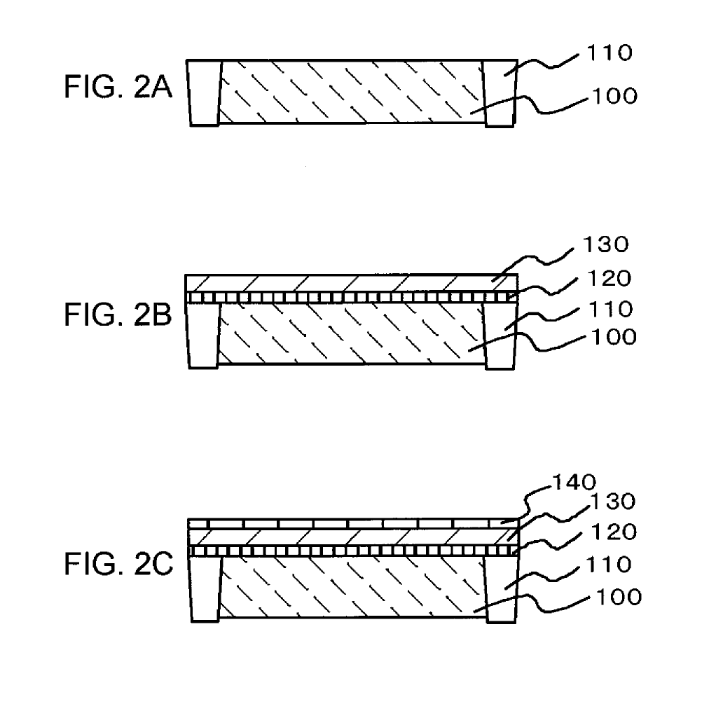

Next, a method of manufacturing the semiconductor device of this embodiment will be explained. FIG. 2A to FIG. 5B illustrate procedures of manufacturing the semiconductor device of this embodiment. The explanation below will deal with an exemplary case where a SiOC film 140 is adopted as the barrier film as described in the above.

The method of manufacturing according to this embodiment includes the processes below:

(I) forming a Hf-containing insulating film (HfSiON film 130) over a substrate (semiconductor substrate 100);

(II) forming a barrier film (SiOC film 140) over the HfSiON film 130; and

(III) forming a fully-silicided gate electrode (NiSi fully-silicided electrode 151) so as to be brought into contact with the SiOC film 140.

The NiSi fully-silicided electrode 151 contains, in a portion thereof brought into contact with the SiOC film 140, either an N-type or P-type impurity segregated therein.

The barrier film has a dielectric constant not larger than that of silicon oxynitride film, and contains elements (i), (ii), and (iii) below as the major constituents:

(i) silicon (Si);

(ii) carbon (C); and

(iii) oxygen (O) or nitrogen (N),

and does not contain any metal element which composes HfSiON film 130 or NiSi fully-silicided electrode 151, as a major constituent at least inside thereof.

### [Process (I)]

First, using a P-type silicon substrate as the semiconductor substrate 100, a device isolation region 110 was formed therein, and the semiconductor substrate 100 was then subjected to ion implantation for forming wells, and P-type ion implantation into channels. A SiO₂ film 120 of 1.0 nm thick was formed by thermal oxidation as the lower insulating film of the gate insulating film (FIG. 2A). A HfSiO film was formed thereon by MOCVD, and then nitrided by annealing in ammonia gas, to thereby convert the film into the HfSiON film 130 of 2.0 nm thick, which serves as the gate insulating film. The thus-obtained HfSiON film 130 was found to have a nitrogen content of approximately 15 atm % (FIG. 2B).

### [Process (II)]

Next, the barrier film is formed over the HfSiON film 130. A process of forming the barrier film in this embodiment includes reactive sputtering of a SiC target in an oxidation atmosphere gas without heating the substrate, and succeeding annealing in a non-oxidation atmosphere gas. More specifically, the SiC target was sputtered in an Ar/O₂ atmosphere so as to proceed RF reactive sputtering, and thereby the SiOC film 140 of 0.3 nm thick was formed as the barrier film on the HfSiON film 130. The substrate is not heated in the process of forming the SiOC film 140. After the formation, the SiOC film 140 was densified typically by annealing in an inert gas or by UV irradiation. The sputtering was carried out under conditions which include a long distance between the target and the substrate, and a low sputtering power, for the purpose of reducing sputtering damage on the gate insulating film, and of precisely controlling the thickness of the film in an extremely thin range. Compositional ratio of carbon in the resultant SiOC film 140 may be adjustable by adjusting the Si/C compositional ratio of the target. The carbon content in this embodiment was found to be approximately 15 atm % (FIG. 2C).

### [Process (III)]

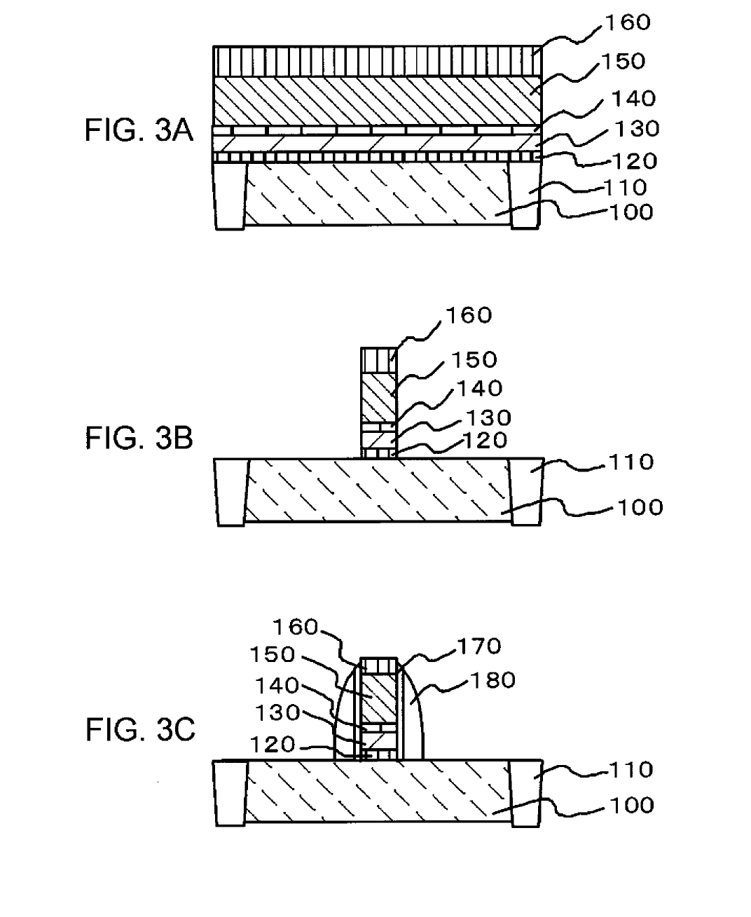

A polysilicon electrode 150 of 50 nm thick was formed by CVD on the SiOC film 140, and As was introduced as a gate impurity at a concentration of 4×10¹⁵ cm⁻². A SiN film 160 of 30 nm thick was then formed thereon as a hard mask for forming the gate electrode (FIG. 3A). The SiN film 160, the polysilicon gate electrode 150, the SiOC film 140, the SiO₂ film 120 and the HfSiON film 130 were then processed by photolithography and dry etching (FIG. 3B).

Next, an offset spacers 170 were formed, and ion implantation for forming extension regions and ion implantation for forming pocket regions were carried out. Sidewalls 180 were then formed, ion implantation for forming the source/drain regions was carried out, and spike-annealing at 1040° C. was carried out as annealing for activating the implanted impurities. Densification of the SiOC film 140 simultaneously took place in this process (FIG. 3C).

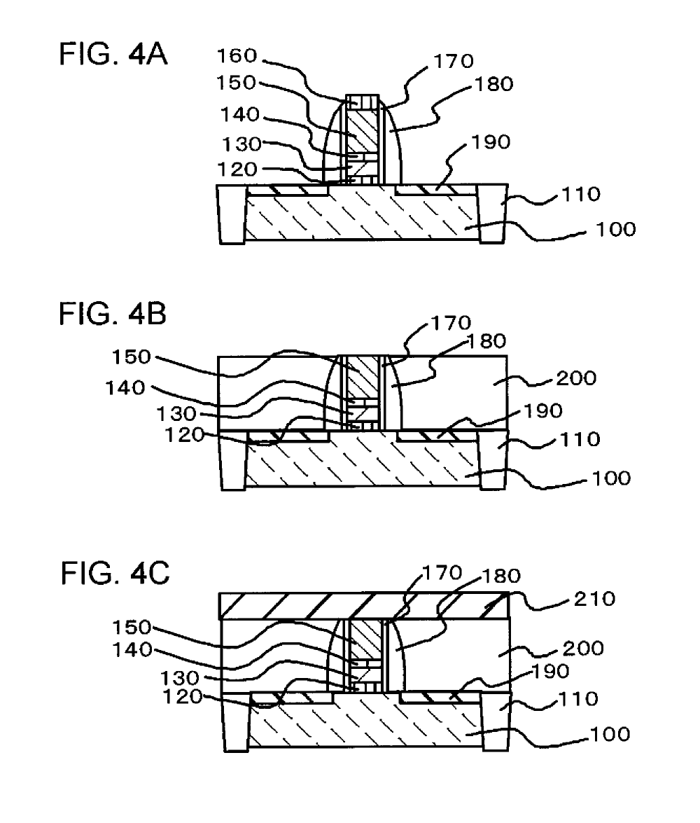

Next, a NiSi film of 25 nm thick was formed as a source/drain silicide film 190, in each of the regions where the source/drain regions are formed later. The polysilicon electrode 150 in this process was covered with the SiN film 160, and was therefore not silicided (FIG. 4A).

A first SiO₂ insulating interlayer 200 was formed so as to cover the entire portion of the device, and then planarized by CMP. Since the CMP, if allowed to proceed as far as the polysilicon electrode 150 exposes, may cause variation in the residual thickness of the gate electrode. The CMP herein was, therefore, carried out under conditions so as to terminate within the range of thickness of the SiN film 160, and so as not to expose the polysilicon electrode 150. The SiN film 160 was then removed by dry etching, while ensuring a selectivity against silicon (FIG. 4B).

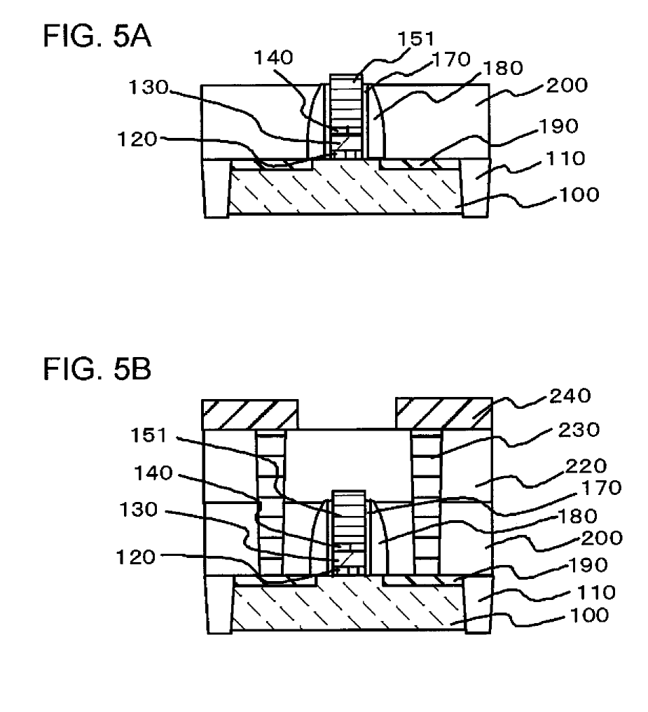

The exposed surface of the polysilicon electrode 150 was treated with a dilute hydrofluoric acid solution so as to remove a native oxide grown thereon, and a Ni film 210 of 30 nm thick was then formed as a metal film for gate a N₂ atmosphere at 400° C. for 60 seconds using a lamp annealer, so as to allow the Ni film 210 and the polysilicon electrode 150 to react, and thereby the NiSi fully-silicided electrode 151 was formed as the fully-silicided electrode. In this process, As which is an impurity preliminarily doped in the polysilicon electrode 150 was expelled towards the SiOC film 140, as the silicidation proceeded from the top to the bottom, and segregated in a portion of the NiSi fully-silicided electrode 151 brought into contact with the SiOC film 140. Portions of the Ni film 210, which remained unreacted on the first SiO₂ insulating interlayer 200 and so forth after the silicidation, were removed by wet etching using an aqueous sulfuric acid-hydrogen peroxide solution (FIG. 5A).

Next, second SiO₂ insulating interlayer 220, contact holes, contact plugs 230 and interconnects 240 were formed, and the product was then annealed at 400° C. in hydrogen gas (FIG. 5B).

The NMIS transistor obtained after the above-described processes, and having the NiSi fully-silicided electrode 151 and the HfSiON film 130 as the gate insulating film, was found to show a work function of 4.3 eV, as judged from the C—V characteristics. It was also found that the work function of the NMIS transistor of this embodiment was 0.2 eV lower than that of an NMIS transistor which was obtained by similar processes except that the SiOC film 140 was not formed. As judged from a capacitance value in the accumulation mode, the equivalent oxide thickness in the accumulation mode of the transistor having the SiOC film 140 was found to be 0.4 nm larger than that of the transistor having no SiOC film 190 formed therein. It was therefore suggested that the diffusion of Ni from the NiSi fully-silicided electrode 151 was suppressed.

Although As was doped into the polysilicon electrode 150 in this embodiment, effects of lowering the work function were obtained also by adopting P, Sb, F, or any other combinations of these elements. The amount of lowering in work function was found to depend on the species of impurity element and the dose.

### Second Embodiment

A second embodiment of the present invention relates to replacement of the NMIS transistor in the first embodiment with a PMIS. A method of manufacturing the PMIS transistor of this embodiment is similar to that described in the first embodiment, except for aspects of difference described below. The aspects of difference relate to that the ion implantation into the channel is carried out using an N-type impurity, that the impurity to be doped into the polysilicon electrode is B, as one example of P-type impurities, and that the conductivity type of the impurities to be implanted into the extension region, the pocket region, and the source/drain regions are inverted.

The PMIS transistor of this embodiment having the NiSi fully-silicided electrode and the gate insulating film, obtained as described the above, was found to have a work function of the gate electrode of 4.9 eV, as judged from the C—V characteristics. It was also found that the work function of the PMIS transistor of this embodiment was 0.3 eV higher than that of a PMIS transistor which was obtained by similar processes except that the SiOC film 140 was not formed. As judged from a capacitance value in the accumulation mode, the equivalent oxide thickness in the accumulation mode of the transistor having the SiOC film 140 was found to be 0.4 nm larger than that of the transistor having no SiOC film 140 formed therein. It was therefore suggested that the diffusion of Ni from the NiSi fully-silicided electrode 151 was suppressed.

Although B was doped into the polysilicon electrode 150 in this embodiment, an effect of elevating work function was obtained also by adopting In, or combination of B and In. The amount of elevation in work function was found to depend on the species of impurity element and the dose.

In two embodiments in the above, processes of independently manufacturing the NMIS and the PMIS were explained. These processes of manufacturing are completely same, except for the individual processes of ion implantation. Accordingly, the both of NMIS and PMIS transistors may readily be formed on the same substrate, simply by specifying regions to be subjected to the individual ion implantation processes by lithographic processes. In other words, a CMOS may readily be configured, without using any complicated process such as separately forming the two types of metal gate electrode for the NMIS and PMIS transistors.

Still alternatively, a transistor having no impurity implanted into the polysilicon electrode 150 may readily be formed by a lithographic process. The work function of the thus-obtained transistor was found to be 4.6 eV. Accordingly, not only the NMIS and PMIS transistors having low threshold voltages, but also a transistor having a high threshold voltage may be formed at the same time, by specifying regions to be subjected to N-type ion implantation, P-type ion implantation, and a region remained unimplanted, by lithographic processes.

### Third Embodiment

A third embodiment of the present invention is different from the above-described first and second embodiments, in that the substrate is not heated in the process of forming the barrier film, but instead annealed in an oxidation atmosphere gas, after the SiC target was sputtered in reactive sputtering in a non-oxidation atmosphere gas. Any other processes in the third embodiment are same as those in the first and second embodiments, as illustrated in FIG. 2A to FIG. 5B.

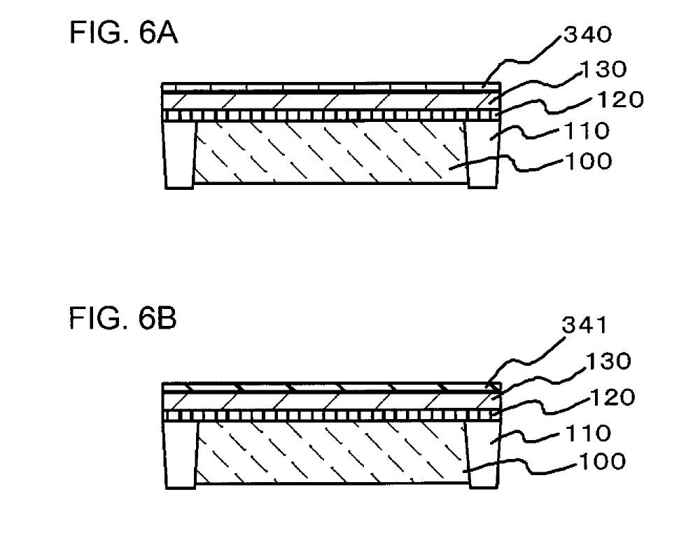

Aspects of the third embodiment, different from those in the first and second embodiments, will be explained below referring to FIGS. 6A and 6B.

After completion of the process illustrated in FIG. 2B, the SiC target was sputtered in an Ar atmosphere by DC sputtering, to thereby form a SiC film 340 of 0.3 nm thick on the HfSiON film 130 (FIG. 6A). The substrate herein was not heated. The compositional ratio of carbon in the finally obtainable SiOC film was found to be approximately 15 atm %, which was adjustable by adjusting the Si/C compositional ratio of the target. The SiC film 340 was then annealed in a N₂ atmosphere containing 10% oxygen at 1000° C. for 5 seconds, to thereby oxidize it to obtain a SiOC film 341 (FIG. 6B).

Thereafter, the NMIS transistor was manufactured according to the processes same as those in the above-described embodiments. The NMIS transistor was found to show a work function of 4.3 eV, as judged from the C—V characteristics. It was also found that the work function of the NMIS transistor of this embodiment was 0.2 eV lower than that of an NMIS transistor which was obtained by similar processes but without forming the SiOC film 341. As judged from a capacitance value in the accumulation mode, the equivalent oxide thickness in the accumulation mode of the transistor having the SiOC film 341 was found to be 0.4 nm larger than that of the transistor having no SiOC film 341 formed therein. It was therefore suggested that the diffusion of Ni from the NiSi fully-silicided electrode 151 was suppressed.

### Fourth Embodiment

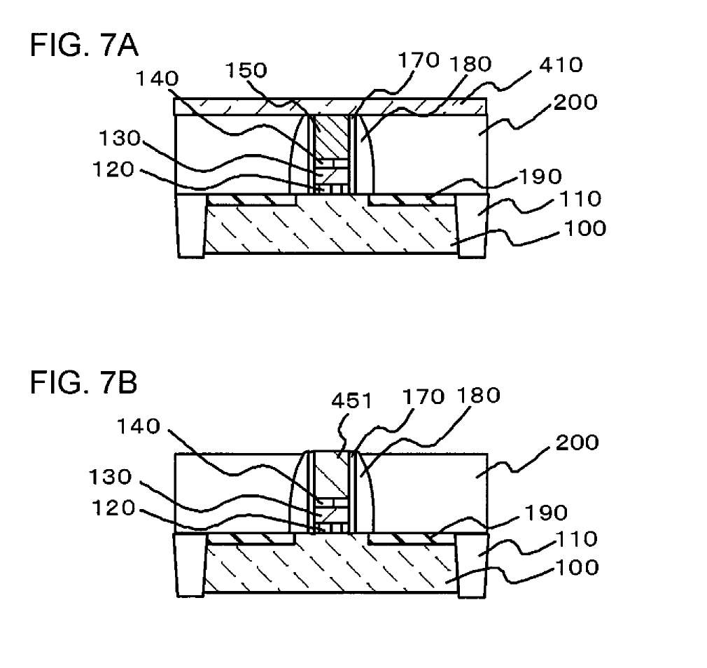

A fourth embodiment of the present invention is similar to the above-described embodiments, except that the fully-silicided electrode was formed using NiSi₂, in place of NiSi. This embodiment will be explained referring to FIGS. 7A and 7B.

The processes up to the first SiO₂ insulating interlayer 200 is planarized by CMP, and the SiN film 160 is removed by dry etching were same as those in the first embodiment. After completion of the process illustrated in FIG. 4B, a native oxide grown on the exposed surface of the polysilicon electrode 150 was removed by dilute hydrofluoric acid treatment, and a Ni film 410 of 15 nm thick was then formed as a metal film for gate silicidation (FIG. 7A).

The Ni film 410 and the polysilicon electrode 150 were then allowed to react using a lamp annealer in a N₂ atmosphere at 650° C. for 60 seconds, to thereby form a NiSi₂ fully-silicided electrode 451 as the fully-silicided electrode. In this process, As preliminarily doped in the polysilicon electrode 150 was expelled towards the SiOC film 140, as the silicidation proceeded from the top to the bottom, and segregated in a portion of the NiSi₂ fully-silicided electrode 451 brought into contact with the SiOC film 140. Portions of the Ni film 410, which remained unreacted on the first SiO₂ insulating interlayer 200 and so forth after the silicidation, were removed by wet etching using an aqueous sulfuric acid-hydrogen peroxide solution (FIG. 7B).

The processes thereafter were similar to those in the first embodiment, and thereby the NMIS transistor having the NiSi₂ fully-silicided electrode 451 and the HfSiON film 130 as the gate insulating film was manufactured. The NMIS transistor of this embodiment was confirmed to be lowered in the work function and increased in the equivalent oxide thickness in the accumulation mode, as compared with an NMIS transistor similarly configured except for having no SiOC film 140, and was found to express effects similar to those in the first embodiment. On the other hand, a PMIS transistor manufactured by implanting B instead of As according to the fourth embodiment was confirmed to be elevated in the work function, and was found to express effects similar to those in the second embodiment.

### Fifth Embodiment

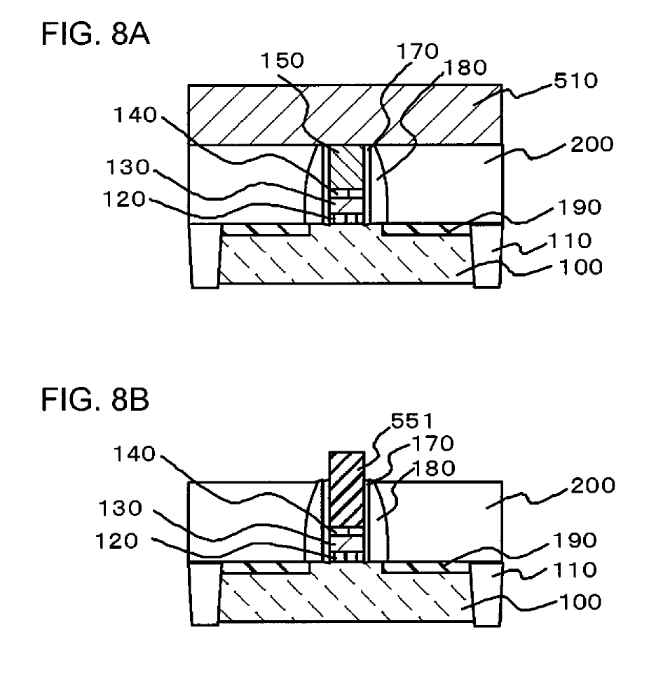

A fifth embodiment of the present invention is similar to the above-described embodiments, except that the fully-silicided electrode was formed using Ni₃₁Si₁₂ which has This embodiment will be explained referring to FIGS. 8A and 8B.

The processes up to the first SiO₂ insulating interlayer 200 is planarized by CMP, and the SiN film 160 is removed by dry etching were same as those in the first embodiment. After completion of the process illustrated in FIG. 4B, a native oxide grown on the exposed surface of the polysilicon electrode 150 was removed by dilute hydrofluoric acid treatment, and a Ni film 510 of 75 nm thick was then formed as a metal film for gate silicidation (FIG. 8A).

The Ni film 510 and the polysilicon electrode 150 were then allowed to react using a lamp annealer in a N₂ atmosphere at 400° C. for 60 seconds, to thereby form a Ni₃₁Si₁₂ fully-silicided electrode 551 as the fully-silicided electrode. In this process, As preliminarily doped in the polysilicon electrode 150 was expelled towards the SiOC film 140, as the silicidation proceeded from the top to the bottom, and segregated in a portion of the Ni₃₁Si₁₂ fully-silicided electrode 551 brought into contact with the SiOC film 140. Portions of the Ni film 510, which remained unreacted on the first SiO₂ insulating interlayer 200 and so forth after the silicidation, were removed by wet etching using an aqueous sulfuric acid-hydrogen peroxide solution (FIG. 8B).

The processes thereafter were similar to those in the first embodiment, and thereby the NMIS transistor having the Ni₃₁Si₁₂ fully-silicided electrode 551 and the HfSiON film 130 as the gate insulating film was manufactured. The NMIS transistor of this embodiment was confirmed to be lowered in the work function and increased in the equivalent oxide thickness in the accumulation mode, as compared with an NMIS transistor similarly configured except for having no SiOC film 140, and was found to express effects similar to those in the first embodiment. On the other hand, a PMIS transistor manufactured by implanting B instead of As according to the fifth embodiment was confirmed to be elevated in the work function, and was found to express effects similar to those in the second embodiment.

While Ni₃₁Si₁₂ was used as the Ni-rich silicide in this embodiment, similar effects were obtained also by using other crystal phases such as Ni₂Si and Ni₃Si.

Several embodiments have been described merely as a part of examples of the present invention, so that material compositions, conditions and so forth may appropriately be modified without departing from the spirit of the present invention. For example, Pt, Pd and so forth may be adoptable as a metal composing the fully-silicided electrode; HfO₂ film, HfAlOx film and so forth may be adoptable as the Hf-containing high-k gate insulating film; and In and so forth may be adoptable as the impurity to be doped into polysilicon for PMIS transistor. While the exemplary cases of adopting a single-crystal Si substrate to the portion composing the channel have been described in the embodiments in the above, similar effects may be obtained by adopting semiconductor substrates other than Si substrate, such as those of SOI type, or those composed of SiGe or strained silicon, so far as conditions for manufacturing of the device, such as dose and acceleration voltage of impurities to be implanted, are appropriately selected.

The process of forming the SiCN film as the barrier film is typically such as sputtering a SiC target in a nitriding atmosphere gas so as to proceed reactive sputtering without heating the substrate (semiconductor substrate), followed by annealing in a non-oxidation atmosphere gas. The process of forming the SiCN film may be similar to the process of forming the above-described SiOC film, except that the SiC target is sputtered in the nitriding atmosphere gas. Effects of the present invention were obtained also in the case where the SiCN film was used as the barrier film.

It is apparent that the present invention is not limited to the above embodiments, that may be modified and changed without departing from the scope and spirit of the invention.

What is claimed is:

1. A semiconductor device comprising:
a substrate;
a Hf-containing insulating film provided over said substrate;
a fully-silicided gate electrode provided over said insulating film; and
a barrier film for blocking diffusion of at least Hf which composes said insulating film and a metal element which composes said fully-silicided gate electrode, provided between said insulating film and said fully-silicided gate electrode so as to be brought into contact with said fully-silicided gate electrode;
said fully-silicided gate electrode containing either an N-type or a P-type impurity segregated in a portion thereof brought into contact with said barrier film, and
said barrier film having a dielectric constant not larger than that of a silicon oxynitride film, and containing elements (i), (ii) and (iii) below as major constituents:
(i) silicon (Si);
(ii) carbon (C); and
(iii) oxygen (O) or nitrogen (N).

2. The semiconductor device as claimed in claim 1,
wherein said barrier film contains no metal element, which composes said insulating film or said fully-silicided gate electrode, as a major constituent at least inside thereof.

3. The semiconductor device as claimed in claim 1,
wherein said element (iii) in said barrier film is oxygen (O).

4. The semiconductor device as claimed in claim 1,
wherein said element (iii) in said barrier film is nitrogen (N).

5. The semiconductor device as claimed in claim 1,
wherein said barrier film is a SiOC film or SiCN film.

6. The semiconductor device as claimed in claim 1,
wherein said barrier film has a carbon content of 5% or more.

7. The semiconductor device as claimed in claim 1,
wherein said barrier film has a carbon content of 30% or less.

8. The semiconductor device as claimed in claim 1,
wherein said barrier film has a thickness of 0.1 nm or larger.

9. The semiconductor device as claimed in claim 1,
wherein said barrier film has a thickness of 1 nm or smaller.

10. The semiconductor device as claimed in claim 1,
wherein said metal element composing said fully-silicided gate electrode is Ni.

11. The semiconductor device as claimed in claim 10,
wherein said fully-silicided gate electrode is composed of nickel monosilicide (NiSi).

12. The semiconductor device as claimed in claim 10,
wherein said fully-silicided gate electrode is composed of nickel disilicide (NiSi₂).

13. The semiconductor device as claimed in claim 10,
wherein said fully-silicided gate electrode is composed of any one of Ni₂Si, Ni₃₁Si₁₂ and Ni₃Si, having a nickel content larger than that of nickel monosilicide.

14. The semiconductor device as claimed in claim 1,
wherein said N-type impurity contains at least one element selected from the group consisting of phosphorus (P), arsenic (As), antimony (Sb) and fluorine (F).

15. The semiconductor device as claimed in claim 1,
wherein said P-type impurity contains boron (B) or indium (In).

16. The semiconductor device as claimed in claim 1,
wherein said barrier film has a dielectric constant not larger than that of a silicon oxide film.

17. The semiconductor device as claimed in claim 1, further comprising:
a first diffusion layer formed in the surficial portion of said substrate on one side of said insulating film; and
a second diffusion layer formed in the surficial portion of said substrate on the other side of said insulating film,
so as to configure a field effect transistor by said first diffusion layer, said second diffusion layer and said fully-silicided gate electrode.

18. The semiconductor device as claimed in claim 17,
wherein said field effect transistor is an NMIS transistor or a PMIS transistor.

19. The semiconductor device as claimed in claim 18,
wherein said NMIS transistor and said PMIS transistor are formed on the same substrate.

20. The semiconductor device as claimed in claim 17,
wherein one of said first diffusion layer and said second diffusion layer is a source diffusion layer, and the other is a drain diffusion layer.

21. A method of manufacturing a semiconductor device comprising:
forming a Hf-containing insulating film over a substrate;
forming a barrier film over said insulating film; and
forming a fully-silicided gate electrode so as to be brought into contact with said barrier film,
said fully-silicided gate electrode containing either an N-type or a P-type impurity segregated in a portion thereof brought into contact with said barrier film, and
said barrier film blocking diffusion of at least Hf which composes said insulating film and a metal element which composes said fully-silicided gate electrode, having a dielectric constant not larger than that of a silicon oxynitride film, and containing elements (i), (ii) and (iii) below as major constituents:
(i) silicon (Si);
(ii) carbon (C); and
(iii) oxygen (O) or nitrogen (N).

22. The method of manufacturing a semiconductor device as claimed in claim 21,
wherein said barrier film contains no metal element, which composes said insulating film or said fully-silicided gate electrode, as a major constituent at least inside thereof.

23. The method of manufacturing a semiconductor device as claimed in claim 21,
wherein in said forming said barrier film, reactive sputtering of a SiC target in an oxidation atmosphere gas, without heating said substrate, is followed by annealing of the grown film in a non-oxidation atmosphere gas.

24. The method of manufacturing a semiconductor device as claimed in claim 21,
wherein in said forming said barrier film, reactive sputtering of a SiC target in a non-oxidation atmosphere gas, without heating said substrate, is followed by annealing of the grown film in an oxidation atmosphere gas.

25. The method of manufacturing a semiconductor device as claimed in claim 21,
wherein in said forming said barrier film, reactive sputtering of a SiC target in a nitriding atmosphere gas, without heating said substrate, is followed by annealing of the grown film in a non-oxidation atmosphere gas.
